(19) United States
(12) Patent Application Publication
(10) Pub. No.: US 2006/0035477 A1
(43) Pub. Date: Feb. 16, 2006

(54) Methods and systems for rapid thermal processing

(76) Inventors: Karen Mai, Taipei Hsien (TW); Ming-Ho Yang, Hsinchu (TW); Tze Liang Lee, Hsinchu (TW); Shih-Chang Chen, Taoyuan County (TW); Chun-Feng Nieh, Hsinchu Hsien (TW)

Correspondence Address: BIRCH STEWART KOLASCH & BIRCH, PO BOX 747, FALLS CHURCH, VA, 22040-0747, US

(21) Appl. No.: 10/916,495

(22) Filed: Aug. 12, 2004

(51) Int. Cl. H01L 21/477; F27D 11/00

(52) U.S. Cl. 438/795; 438/663; 219/411; 219/413

(57) ABSTRACT

Methods for rapid thermal processing of semiconductor substrates are provided. An exemplary method comprises directing radiant heat energy emitted from a heat source toward a backside surface of the semiconductor substrate. Systems for rapid thermal processing also are provided.

### BACKGROUND

The present invention relates to semiconductor manufacturing and, in particular, to rapid thermal processing.

Rapid thermal processing (RTP) has become widely used in various stages of semiconductor manufacturing. For example, rapid thermal processing is used for the chemical deposition of various films on semiconductor wafers. Rapid thermal processing has also been used in the annealing of ion or dopant implanted semiconductor wafers. Because the operating temperature in rapid thermal processing can be rapidly increased or decreased, the required processing time is short and the efficiency is high.

In many RTP applications the heat treatment often needs to be conducted under specific atmospheric conditions with a specific gas composition flowing through the processing chamber where the wafer is being treated. FIG. 1 illustrates an example of a conventional RTP reactor for heat-treating a semiconductor wafer in a flowing gas composition. The reactor 10 comprises a processing chamber 11 where a semiconductor wafer can be treated. A rotatable susceptor 12 is mounted within the processing chamber 11. A wafer 13 to be processed is held and supported by susceptor 12, and can be rotated along with the rotatable susceptor 12. In addition, the apparatus also comprises a gas delivery system with a gas inlet 14 at one end of the processing chamber 11, and a gas outlet 15 at the other end of the processing chamber 11. A gas composition typically flows into processing chamber 11 at room temperature, while the operating temperature in processing chamber 11 is very high, e.g., from 500° C. to 1200° C. A heat source is located above processing chamber 11 such that the front surface of wafer 13 can be radiated by the heat emitted from heat source 16. Heat source 16 comprises a plurality of heating units each having a halogen lamp 17 therein.

Since there typically are some semiconductor device patterns on the surface of the front side of the semiconductor substrate, heat conduction is non-uniform if the patterns are facing the heat source. The non-uniformity results in variation of electrical characteristics. For example, the higher the local OD(active region) density is, the higher the non-salicide sheet resistance is.

As is well known in the art, it is critical that during the rapid thermal processing of a wafer, the entire surface of the wafer is heated uniformly. Non-uniformity in temperature distribution across the wafer surface can result in dislocations and distortion in the wafer. In conventional rapid thermal processing, however, it is often very difficult to achieve temperature uniformity across the wafer surface. As is apparent from FIG. 1, it is difficult to design the spatial arrangement of the wafer and the individual heating units so that the radiant heat energy received at each point on the wafer surface is the same. As a result, radial temperature gradients from the edge to the center of the wafer may form. In particular, the outer edge of the wafer often receives the least radiation energy. As shown in FIGS. 2A and 2B, for the 1075° C. spike, the temperature of inner range T1-T3 is significantly higher than outer range throughout the thermal cycle. The temperature spread between the inner and the outer range is around 12° C. In addition, rapid thermal processing is typically conducted in a very short cycle of 2-15 minutes, for example. The wafer is rapidly heated to a very high temperature and is cooled rapidly. Any small variations in heat radiation at different points of the wafer surface can cause drastic temperature variations. As a result, the thermal stress at different points of the wafer surface can vary, causing the distortion of the wafer. In the case of rapid thermal chemical vapor deposition, the deposition rate at the different points on the wafer surface can vary due to temperature non-uniformity, thus resulting in non-uniformity in the thickness of the deposited film.

In addition, much effort has been focused on real-time control of the radiation energy emitted from individual lamps to achieve heat uniformity. In one method, an optical pyrometer is used with a wavelength of two to three micrometers (μm), to monitor temperatures at different points on the wafer backside surface. The monitored temperature parameters are then processed by a processor such as a computer to generate a new set of parameters. The power of the individual heating units is then adjusted based on the new parameters to compensate for the temperature differences at different points on the wafer surface to achieve temperature uniformity. In order to achieve temperature uniformity using this method, however, it is important that accurate temperature measurements are obtained by the pyrometer. In practice, the temperature measurements of the pyrometer are often distorted and inaccurate due to the interference from various factors during processing. Examples of such factors include wafer reflectivity, radiation from radiant lamps, radiant energy passing through around the wafer, radiant energy reflected back by the walls of the processing chamber, and heat energy generated by the chemical reaction during the deposition process.

### SUMMARY

An embodiment of a method for rapid thermal processing of a semiconductor substrate comprises directing the radiant heat energy from a heat source toward a backside surface of the semiconductor substrate. Moreover, a pyrometer can be placed at the front surface of the semiconductor substrate to measure the actual temperature thereof.

An embodiment of a system for rapid thermal processing of a semiconductor substrate comprises a heat source and a reflector. The heat source provides radiant heat energy for rapid thermal processing. The reflector reflects the radiant heat energy and redirects the reflected radiant heat energy to the backside surface of the semiconductor substrate. Furthermore, a pyrometer can be arranged at the front surface of the semiconductor substrate to measure the actual temperature thereof, without being affected by heat source temperature or radiant heat energy emitted from the heat source directly.

Another embodiment of a system for rapid thermal processing of a semiconductor substrate comprises a heat source and a susceptor. The heat source radiates heat energy for rapid thermal processing. The suspetor supports the semiconductor substrate such that the backside surface thereof faces the heat source. In addition, a pyrometer can be arranged at the front surface of the semiconductor substrate to measure the actual temperature thereof, without being affected by heat source temperature or radiant heat energy emitted from the heat source directly.

Another embodiment of provides a method and apparatus for rapid thermal processing. The radiant heat energy from the heat source is directed to the backside surface of the semiconductor substrate and the front surface of the semiconductor substrate is not exposed to the radiant heat energy. As a result, the patterns on the front surface of the semiconductor substrate do not influence heat flux uniformity. Moreover, since the heat source is not arranged at the front surface of the semiconductor substrate, a pyrometer can be placed thereat. An actual temperature of the front surface of the semiconductor substrate can thereby be measured for real-time control of the radiation energy emitted from individual lamps of the heat source to achieve heat uniformity.

### BRIEF DESCRIPTION OF THE DRAWINGS

FIG. 1 illustrates an example of a conventional RTP reactor for heat-treating a semiconductor wafer in a flowing gas composition;

FIGS. 2A and 2B illustrate temperature distribution and spread of a semiconductor substrate processed with the conventional RTP of FIG. 1;

FIG. 3 illustrates an embodiment of a method for rapid thermal processing of a semiconductor substrate;

FIG. 4 illustrates another embodiment of a method for rapid thermal processing of a semiconductor substrate;

FIG. 5 illustrates repeatability and uniformity of rapid thermal processing at 1055° C. with a ramp rate of 250° C./s using the method of FIG. 4.

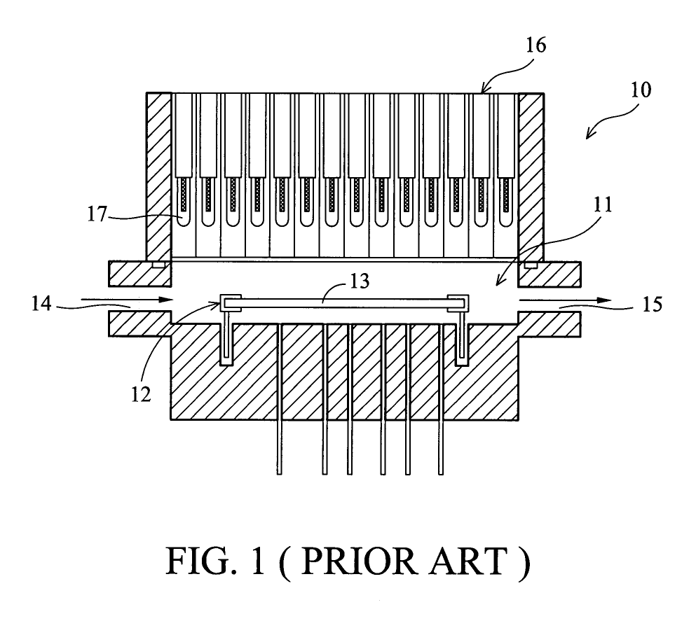

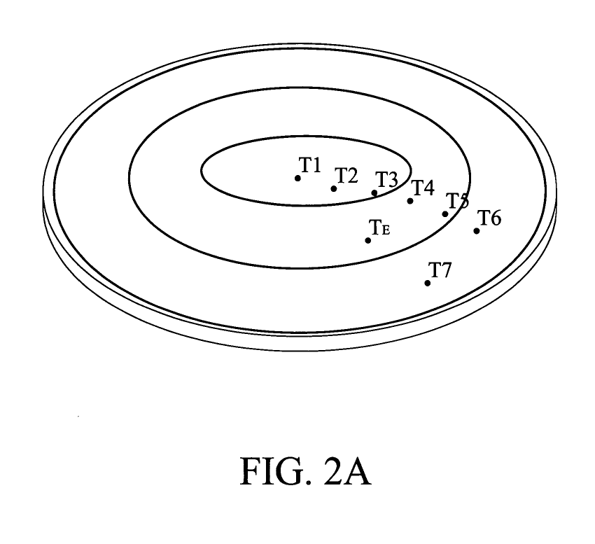

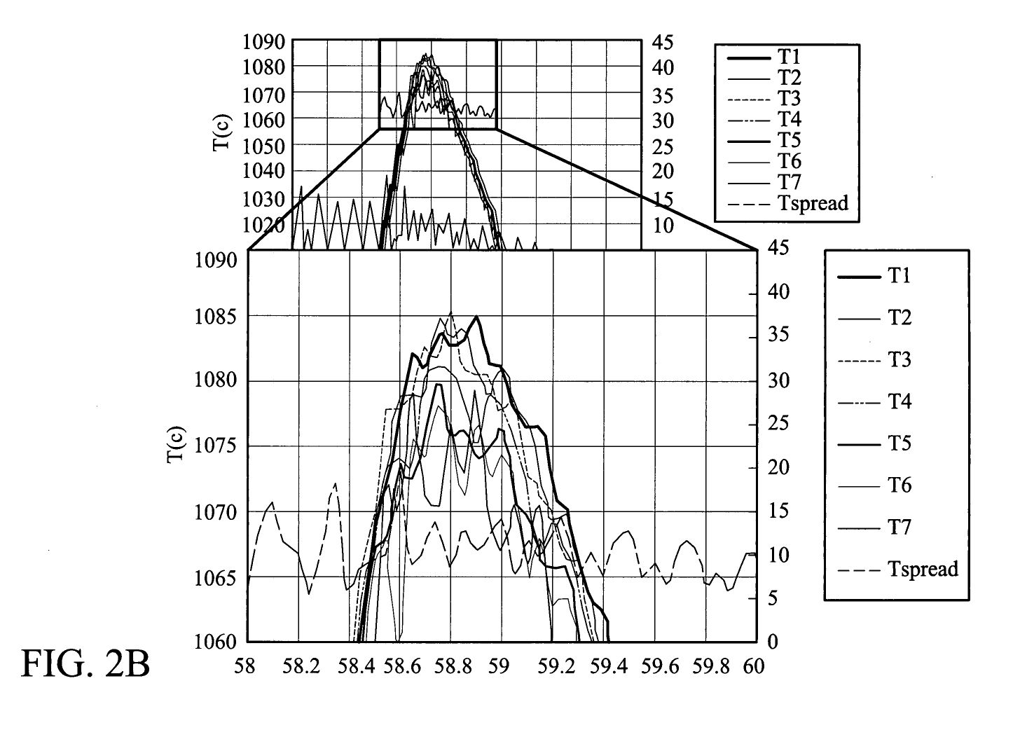

### DETAILED DESCRIPTION

Since heat conduction is pattern dependent, if the patterns on the front surface of a semiconductor substrate face a heat source, it is desirable to prevent the patterns from direct heat radiation produced by the heat source.

Methods and systems for rapid thermal processing are provided. In some embodiments of the present invention, radiant heat energy is directed to the backside surface of the semiconductor substrate and the front surface of the semiconductor substrate is not directly exposed to the radiant heat energy. As a result, the patterns on the front surface of the semiconductor substrate may not influence heat flux uniformity. Moreover, since the heat source is not arranged at the front surface of the semiconductor substrate, a pyrometer can be placed there. The actual temperature of the front surface of the semiconductor substrate can be measured and used for real-time control of the radiation energy emitted from individual lamps, for example, to improve heat uniformity.

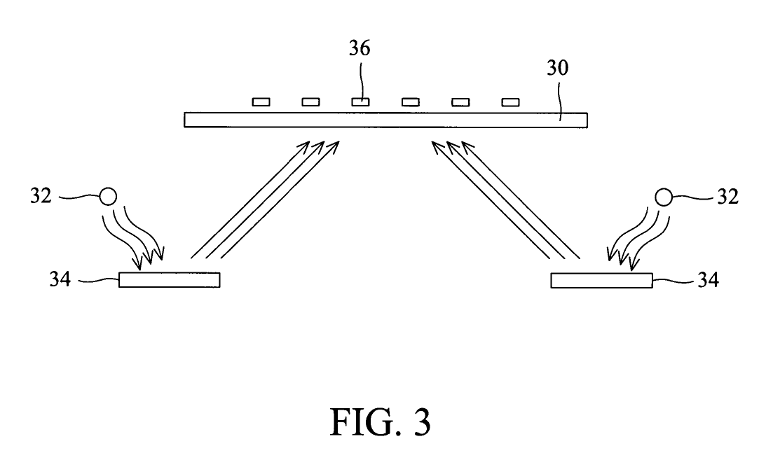

An embodiment of a system for rapid thermal processing of a semiconductor substrate is depicted in FIG. 3. As shown in FIG. 3, this embodiment comprises a heat source 32 and a reflector 34. The heat source 32 provides the radiant heat energy for rapid thermal processing. The front surface of the semiconductor substrate 30 is not exposed to the heat source 32. The reflector 34 reflects the radiant heat energy from the heat source 32 and re-directs the reflected radiant heat energy toward the backside of the semiconductor substrate 30. Moreover, at least one pyrometer 36 can be arranged over the front surface of the semiconductor substrate 30. An accurate temperature of the front surface of the semiconductor substrate 30 can thereby be obtained, and the measurement is not affected by heat source temperature or radiant heat energy emitted from the heat source directly.

FIG. 3 also illustrates an embodiment of a method for rapid thermal processing of a semiconductor substrate. To prevent the patterns on the front surface of a semiconductor substrate from direct heat radiation produced by the heat source, this embodiment comprises directing radiant heat energy emitted from the heat source toward a backside of the semiconductor substrate. As shown in FIG. 3, the heat source 32 is provided to radiate heat energy for rapid thermal processing. The front surface of the semiconductor substrate 30 is not exposed to the radiation from the heat source 32. A reflector 34 reflects the radiant heat energy from the heat source 32 and re-directs the reflected radiant heat energy toward the backside of the semiconductor substrate 30. Furthermore, this embodiment comprises measuring the temperature of the front surface of the semiconductor substrate 30. In this regard, at least one pyrometer 36 is located near the front surface of the semiconductor substrate 30. The measured temperature can be used for real-time control of the radiation energy emitted from individual heat sources to achieve better heat uniformity.

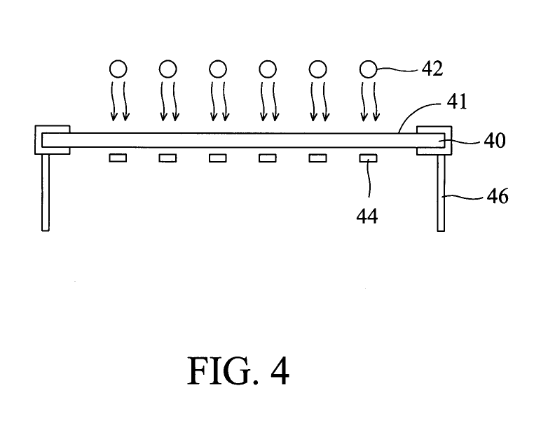

An embodiment of a system for rapid thermal processing of a semiconductor substrate is depicted in FIG. 4. The equipment comprises a heat source which may be a heating lamp 42 and a susceptor 46. The heat source 42 provides radiant heat energy for heating the semiconductor substrate 40. The susceptor 46 supports the semiconductor substrate 40 and faces the backside of the semiconductor substrate 40 toward the heat source 42.

FIG. 4 illustrates another embodiment of a method for rapid thermal processing of a semiconductor substrate. In this embodiment, a semiconductor substrate 40 is flipped, i.e., the substrate is inverted so the backside surface 41 faces upward. At least one heat source 42 is placed over the backside surface of the semiconductor substrate 40. The backside surface of the semiconductor substrate 40 is directly exposed to the heat sources 42. Since the front surface of the semiconductor substrate 40 is not exposed to the heat sources 42, at least one pyrometer 44 can be placed at the front surface of the semiconductor substrate 40.

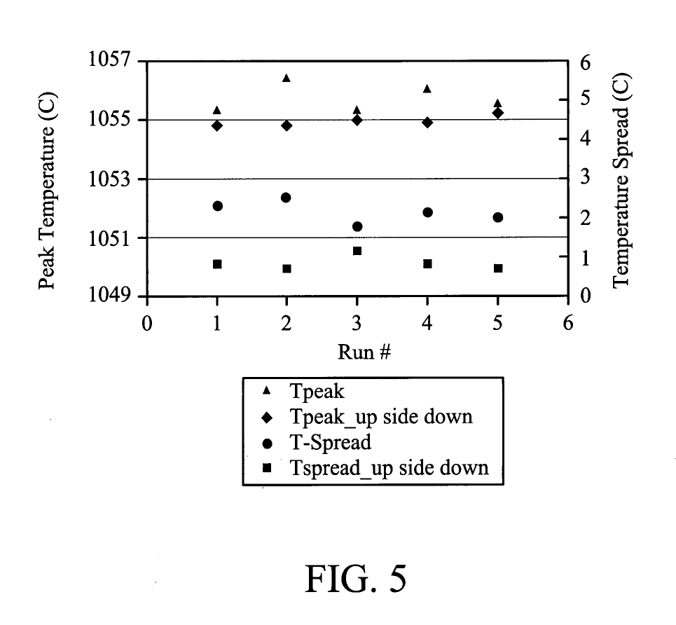

The repeatability of rapid thermal processing is critical for mass production. FIG. 5 illustrates the repeatability of rapid thermal processing at 1055° C. with a ramp rate of 250° C./s according to conventional RTP and an embodiment of a method for rapid thermal processing. As shown in FIGS. 5, triangle and diamond data points are peak temperatures of conventional RTP and the embodiment of a method for rapid thermal processing respectively. Fluctuation of the peak temperature of conventional RTP is more severe than that of the embodiment of a method for rapid thermal processing. The peak temperature of the upside down heating wafer shows better repeatability of rapid thermal processing than the conventional RTP wafer. Circle and square data points are the temperature spread of conventional RTP and the embodiment of a method for rapid thermal processing respectively. The temperature spread of conventional RTP is higher than that of the embodiment of a method for rapid thermal processing. The temperature spread of the upside down heating wafer shows better uniformity than the conventional RTP wafer, due to fewer patterns on the backside surface making heat flux absorption and reflection more uniform.

While the invention has been described by way of example and in terms of several embodiments, it is to be understood that the invention is not limited to the disclosed embodiments. To the contrary, it is intended to cover various modifications and (as would be apparent to those skilled in the art). Therefore, the scope of the appended claims should be accorded the broadest interpretation so as to encompass all such modifications.

What is claimed is:

1. A method for rapid thermal processing of a semiconductor substrate, comprising:
directing radiant heat energy emitted from a heat source toward a backside of the semiconductor substrate.

2. The method as claimed in claim 1, wherein the radiant heat energy is directed to the backside of the semiconductor substrate by at least one reflector.

3. The method as claimed in claim 1, further comprising measuring temperature of a front surface of the semiconductor substrate.

4. The method as claimed in claim 3, wherein temperature of the front surface of the semiconductor substrate is measured by a pyrometer disposed over the front surface of the semiconductor substrate.

5. The method as claimed in claim 1, wherein the heat source is located at the backside surface of the semiconductor substrate.

6. A system for rapid thermal processing of a semiconductor substrate, comprising:
a heat source for emitting radiant heat energy; and
a reflector for directing radiant heat energy emitted from the heat source toward a backside of the semiconductor substrate.

7. The system as claimed in claim 6, further comprising:
means for measuring a temperature of the front surface of the semiconductor substrate.

8. The system as claimed in claim 6, further comprising a pyrometer, located over the front surface of the semiconductor substrate, for measuring a temperature of the front surface of the semiconductor substrate.

9. A system for rapid thermal processing of a semiconductor substrate, comprising:
a heat source for emitting radiant heat energy; and
a susceptor for supporting the semiconductor substrate and facing the backside of the semiconductor substrate toward the heat source.

10. The system as claimed in claim 9, further comprising a pyrometer, over the front surface of the semiconductor substrate, for measuring the temperature of the front surface of the semiconductor substrate.

11. The system as claimed in claim 9, further comprising:
means for measuring a temperature of the front surface of the semiconductor substrate.
